(19) United States
(12) Patent Application Publication
(10) Pub. No.: US 2013/0048049 A1
(43) Pub. Date: Feb. 28, 2013

(54) METHOD AND APPARATUS FOR CONTROLLING PHOTOVOLTAIC PLANT OUTPUT USING LAGGING OR LEADING TRACKING ANGLE

(71) Applicant: Kent Flanery, Worthington, KY (US)

(72) Inventor: Kent Flanery, Worthington, KY (US)

(21) Appl. No.: 13/214,704

(22) Filed: Aug. 22, 2011

(51) Int. Cl. H01L 31/052

(52) U.S. Cl. 136/246

(57) ABSTRACT

A method and apparatus for operating a tracker to cause a solar module to track a position of the sun at a first angle of incidence, and, in response to identification of a lag or lead trigger condition, determine a second angle of incidence calculated by increasing or decreasing the first angle of incidence by a lagging or leading factor so as to lower electrical current output of the solar module, and thereafter operating the tracker to cause the solar module to track the position of the sun at the second angle of incidence.

### FIELD OF THE INVENTION

Embodiments of the invention relate to methods and apparatuses for controlling photovoltaic plant output.

### BACKGROUND OF THE INVENTION

Photovoltaic power generation systems convert solar radiation to electrical current using photovoltaic modules. Since direct irradiance (and therefore electrical current output) varies according to the cosine of the angle at which the Sun's rays strike the photovoltaic modules (the “angle of incidence”), in systems where the photovoltaic modules remain in a fixed position, electrical current output rises and falls as Sun travels from the eastern to western horizon. To provide increased (and more consistent) power generation over the course of a day, power generation systems can employ electromechanical solar trackers that change the inclination of photovoltaic modules to maintain a fixed angle of incidence between the Sun and the photovoltaic modules.

Solar trackers typically employ an algorithm that uses the current date and time and the latitude and longitude of the system as inputs to approximate the position of the sun. With the position of the Sun approximated, the photovoltaic modules can be positioned at substantially zero degrees (the optimum angle of incidence) to the Sun. The inclination of the photovoltaic modules may then be adjusted at regular intervals throughout the day so that the angle of incidence remains constant. Simple trackers such as these, however, generally operate without external inputs and thus fail to account for other variables that may effect power generation, such as ambient air temperature or module temperature. The trackers also fail to account for other factors or desired operating characteristics, such as desired plant output. Accordingly, more refined methods of controlling photovoltaic plant output are needed that can emphasize desired operating characteristics, and account for variables besides the approximated position of the Sun.

### BRIEF DESCRIPTION OF THE DRAWINGS

FIGS. 1A-1B are respective side and front views of a photovoltaic module and electromechanical tracker, according to an exemplary embodiment.

FIG. 2 is a side view of the FIG. 1A photovoltaic module showing different operating states.

FIG. 3 is a side view of a photovoltaic module and electromechanical tracker implementing an exemplary method described herein.

FIG. 4 is a side view of a photovoltaic power generation system having photovoltaic modules equipped with electromechanical trackers implementing an exemplary method described herein.

FIG. 5 is a flow chart of an exemplary method described herein.

### DETAILED DESCRIPTION OF THE INVENTION

In the following detailed description, reference is made to the accompanying drawings which form a part hereof, and which illustrate specific embodiments of the invention. These embodiments are described in sufficient detail to enable those of ordinary skill in the art to make and use them. It is also understood that structural, logical, or procedural changes may be made to the specific embodiments disclosed herein without departing from the spirit or scope of the invention.

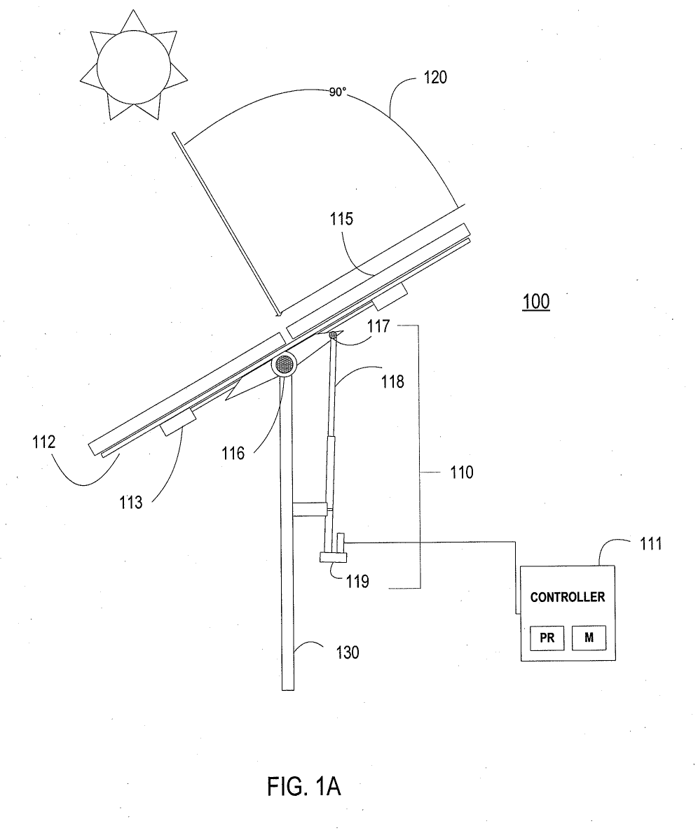

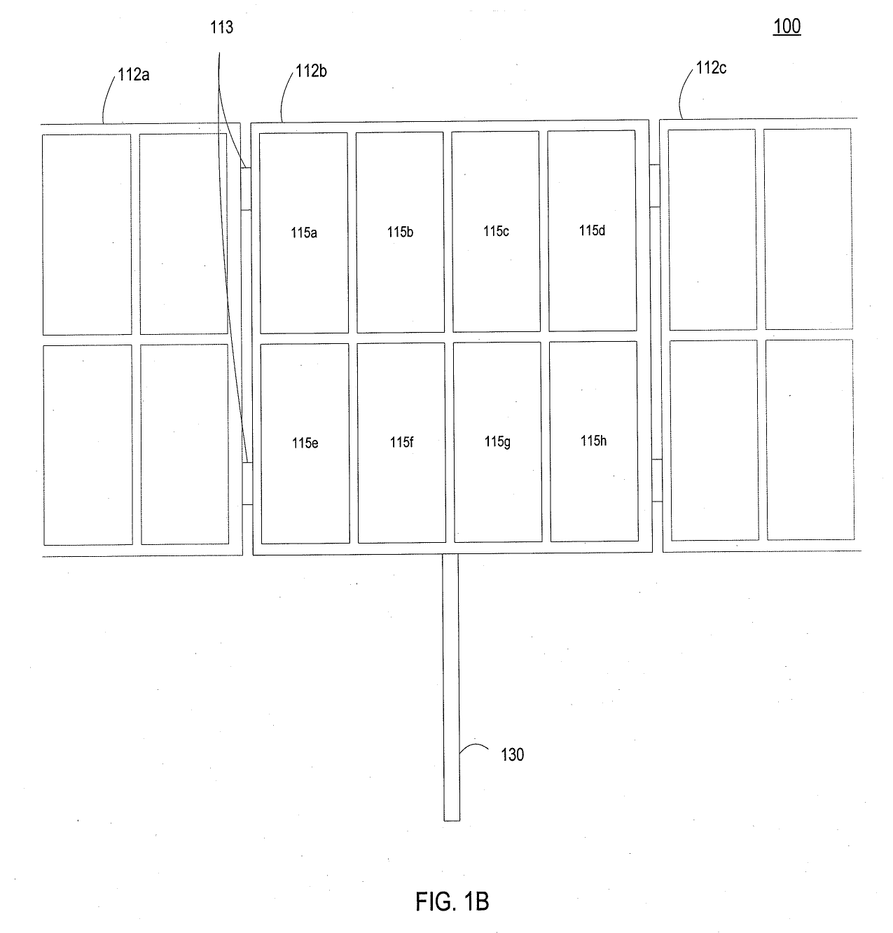

FIG. 1A illustrates a side view of a system 100 used to control the inclination of a solar module 115 according to an exemplary embodiment. As can be seen in FIG. 1A, one or more solar modules 115 are mounted to a module support 112. The system 100 includes an electromechanical tracker 110 that is used to control the inclination of module support 112. Module support 112 is mounted on a rotatable bearing and housing 116, which is supported by post 130, thus permitting solar modules 115 to be positioned at a desired angle of incidence 120 (here, 0 degrees) to the Sun as the Sun traverses the sky.

As illustrated in FIG. 1B, the post 130 can accommodate multiple module supports 112a-c, each carrying multiple solar modules 115a-h. Module supports 112a-c can be joined together along rails 113. Three module supports 112a-c are illustrated in FIG. 1B; this is merely exemplary. Eight solar modules 115a-h are illustrated on each module support 112a-c in FIG. 1B; this is also merely exemplary.

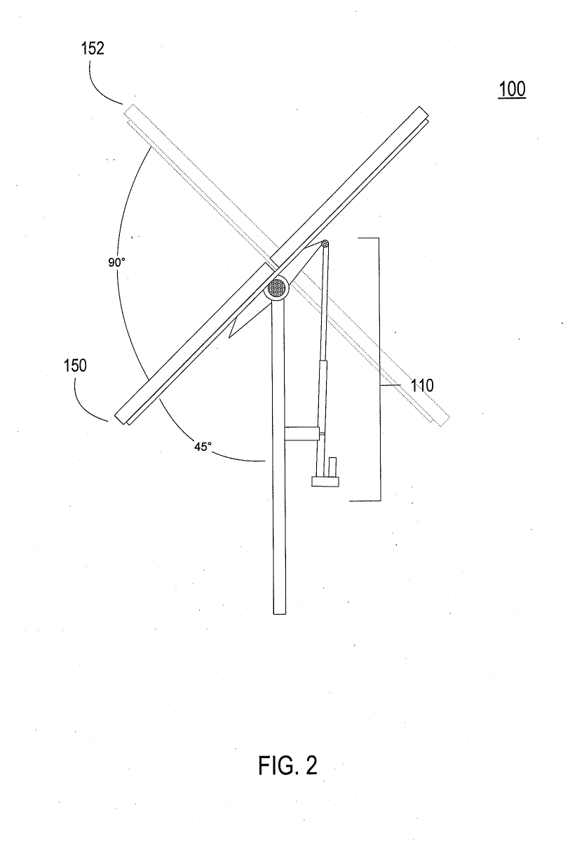

As illustrated in FIG. 2, the electromechanical tracker 100 is capable of rotating module support 112 through a 90 degree path from a first end position 150 to a second end position 152. In both end positions 150, 152, the module support 112 forms a 45 degree angle with the post 130. Thus, in a horizontal position, the module support 112 would form a 90 degree angle with the post 130. It should be understood, of course, that the module support 112 may rotate through a path that is larger than or smaller than 90 degrees. Furthermore, the module support 112 may rotate through a path of 90 degrees but may form different angles with the post 130 at the end positions 150, 152. For example, at first end position 150 the module support 112 may form an angle of 40 degrees with the post 130 while at the second end position 152 the module support 112 forms an angle of 50 degrees with the post 130. It should be further understood that the angle of the end positions 150, 152 with respect to the post 130 and the amount of rotation of the module support 112 may vary according to the location of the system 100 on the globe and the terrain on which the tracker is located. The module support 112 may be modified to allow for the solar module 115 to best track the path of the Sun as it traverses the sky.

Referring again to FIG. 1A, the module support 112 is coupled to a lever arm 117, which is capable of actuating module support 112 about bearing and housing 116. The electromechanical tracker 110 comprises an AC or DC actuator motor 119 and screw arm 118 secured both to post 130 and lever arm 117.

The actuator motor 119 is controlled by a controller 111. The controller 111 generates tracking control signals that are sent to the actuator motor 119. The actuator motor 119 advances or retracts screw arm 118 in the direction and the amount indicated by the tracking control signals. In operation, lever arm 117 is actuated (adjusting the inclination of module support 112) as the actuator motor 119 advances or retracts screw arm 118. The controller 111 is thus able to position the module support 112 at any inclination along the module support's 112 path of rotation.

The controller 111, which comprises at least a processor PR and memory M, contains algorithms used to control the inclination of the module support 112 so that the solar module 115 tracks the path of the sun. For example, the controller 111 may contain an algorithm that positions the module support 112 at the first end position 150 at sunrise so that solar modules 115 are pointed at the sun. As the Sun rises in the sky, the controller 111 periodically sends tracking control signals to the actuator motor 119, causing the screw arm 118 to adjust the inclination of the module support 112 so that the module support 112 and the solar module 115 remain pointed at the Sun as the Sun moves across the sky during the day.

It is typically desired to have solar modules 115 pointed directly at the Sun so that the Sun is at an angle of incidence of substantially 0 degrees with the solar module 115. This maximizes the ability of solar modules 115 to generate electrical power from the solar energy under optimum operating conditions (i.e., no clouds). If solar modules 115 are at an inclination such that an angle of incidence of the Sun light is less or greater than zero degrees, solar modules 115 may generate less power and in some cases operate less efficiently. Generally, after the Sun sets, controller 111 sends a tracking control signal to actuator motor 119 to move the module support 112 to a near flat position generally defined as less than 10 degrees tilt so that solar modules 115 are in position for the Sun rise the next morning. It maintains this idle or “stow” position until the next morning when it resumes normal tracking.

As noted earlier, it is typically desired that electromechanical trackers 110 will point solar modules 115 directly at the Sun so that the Sun light has the optimal angle of incidence with the solar modules 115. However, under certain conditions, it may be desired to adjust the inclination of the s solar modules 115 to a less-than-optimal angle of incidence. There are a number of situations where such functionality would be useful.

In addition, this functionality can be desirable to track away from the sun at times to avoid undesirable conditions, such as high module temperature at times of high ambient condition. Thus, in such locations, an angle of incidence that is not otherwise strictly optimal may be desired because it will decrease the operating temperature of solar modules 115. Importantly, every degree centigrade drop in the operating temperature of solar modules 115 provides an approximately one-quarter percent increase in electrical current output.

Other undesirable conditions are open circuit conditions caused by a system disconnection of solar modules 115 from associated inverters that aggregate the electrical energy generated by the solar modules 115. Such disconnections may occur at times where decreased energy output is desired. Since operating solar modules 115 at an angle of incidence that is not strictly optimal decreases output of solar modules 115, instead of disconnecting solar modules 115 from the inverters, solar modules 115 can be positioned so as to generate less overall energy output. Adjusting solar module 115 output in this manner allows management of system conditions where too much solar energy is being generated; this capability to turn down output artificially by effectively turning down irradiance without causing inverter shutdown or solar module 115 disconnection is advantageous in increasing the life of solar modules 115. To permit such functionality, commands to set a desired solar module 115 output can be received at controller 111 from a connected inverter or directly from a power plant control system. The command to set desired solar module 115 output can be based on, among other things, active or reactive power targets set at the inverter or power plant control system.

Another example of beneficial functionality provided by operating the panels at an angle of incidence that is not strictly optimal occurs on cold, clear days where excessive voltage conditions occur or on days of very high irradiance when the inverters which aggregate the electrical energy generated by the solar modules 115 are operating at or near a clipping condition. In such conditions, an angle of incidence that is not strictly optimal decreases overall output of aggregated solar modules 115, thus avoiding inverter clipping conditions.

A further example of a beneficial altered angle of incidence is in the context of cleaning solar modules 115. For instance, upon signaling of approaching inclement weather, controller 111 can position solar modules 115 at a predetermined tracking angle selected to prevent precipitation or cleaning fluids from pooling on the solar modules 115 and optimize module cleansing.

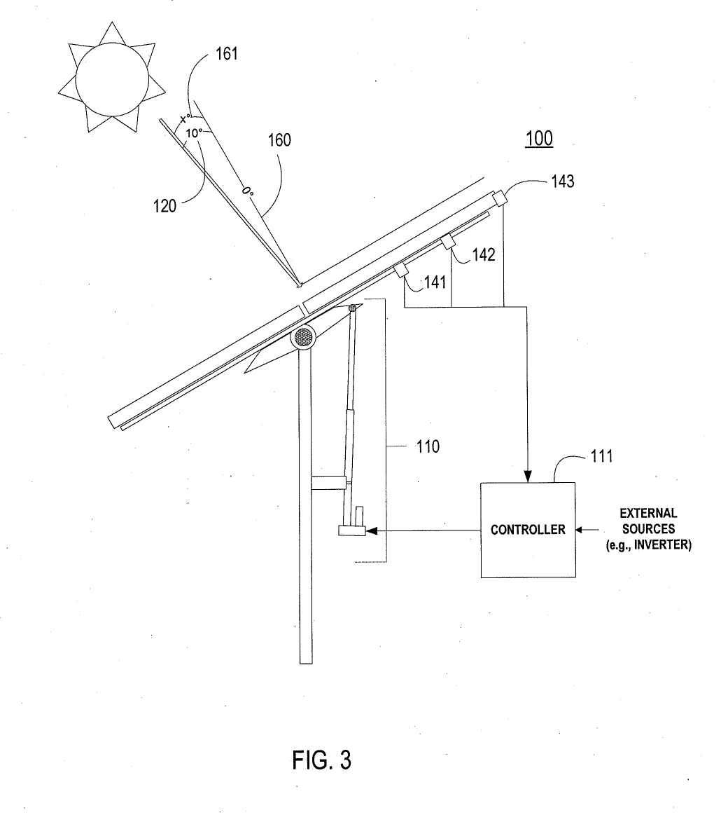

Accordingly, FIG. 3 illustrates an exemplary embodiment of solar tracking system 100 in which electromechanical tracker 110 is controlled by controller 111 to actuate module support 112 (and solar module 115) to a desired angle of incidence 120 that lags or leads an optimal angle of incidence 160 by a lag or lead factor 161 of x degrees. As shown in FIG. 3, the optimal angle of incidence 160 is 0 degrees and the lag factor is 10 degrees; thus, the desired angle of incidence 120 is 10 degrees. It should be appreciated that, as noted above, direct irradiance varies with the cosine of the angle of incidence, so operation of the solar module 115 at the lag factor 161 of 10 degrees decreases direct irradiance by) 1−cos(10°, or approximately one and a half percent, reducing electrical current output from a solar module 115 by an approximately equivalent amount. A larger lag factor 161 of, for instance, 30 degrees, would decrease direct irradiance by approximately thirteen and a half percent. It should be appreciated that lagging or leading the optimal angle of incidence 160 by a respective lag or lead factor 161 of the same number of degrees will produce approximately the same decrease in direct irradiance and electrical current output.

FIG. 3 also shows the incorporation of a module temperature sensor 141, ambient air temperature sensor 142 and air movement and direction sensor 143 to solar tracking system 100 to provide controller 111 with additional information to use to, among other things, trigger or cease lagging or leading operations, or determine a desired angle of incidence 120 for lagging or leading operations

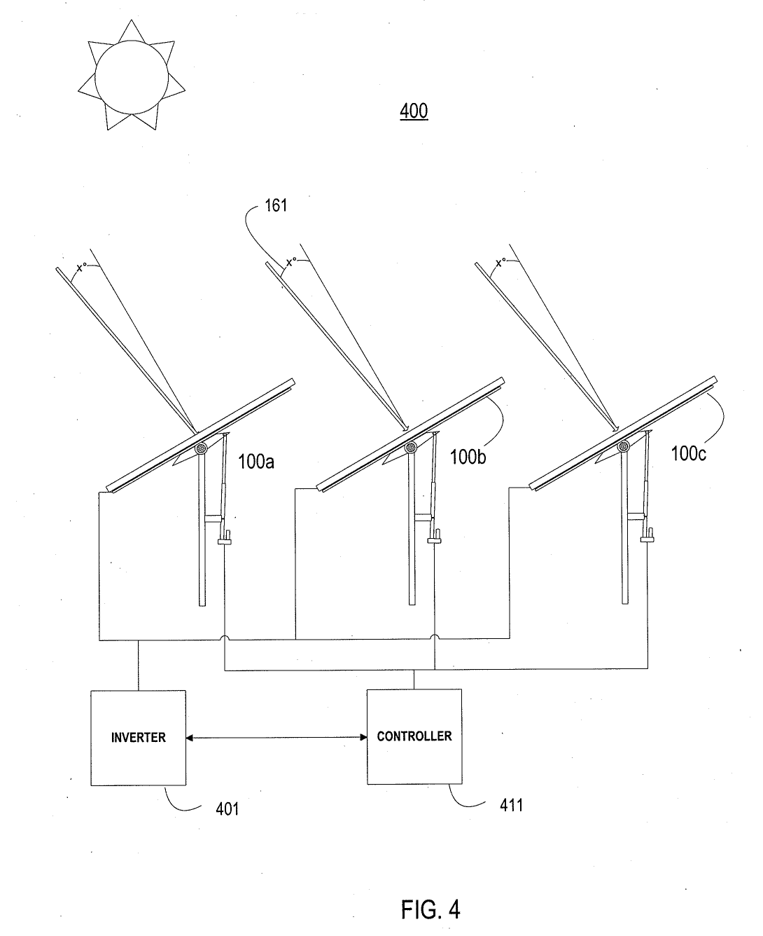

FIG. 4 shows a power generation system 400 that has a plurality of solar tracking systems 100a, 100b and 100c arranged in rows. The solar tracking systems 100a, 100b and 100c may be arranged in close proximity to each other so as to maximize the number of solar tracking systems 100 that are located in a given area. Electromechanical trackers 110 on each solar tracker 100a, 100b and 100c are connected to a common controller 411 that controls actuation of associated module supports 112 and solar modules 115 mounted thereon. In another embodiment, each solar tracking system 100 may have its own controller 111 (as shown in FIGS. 1A-B and 3) to control the actuator motor 119 and screw arm 118 on each solar tracking system 100, with common controller 411 providing operational commands to these controllers 111. The electrical outputs of each solar tracking system 100a, 100b and 100c are connected to an inverter 401, which can provide operating information, such as total DC voltage level or DC voltage or current level at each solar tracking system 100a, 100b and 100c to controller 411. Controller 411 can then use this information to trigger lagging or leading operations.

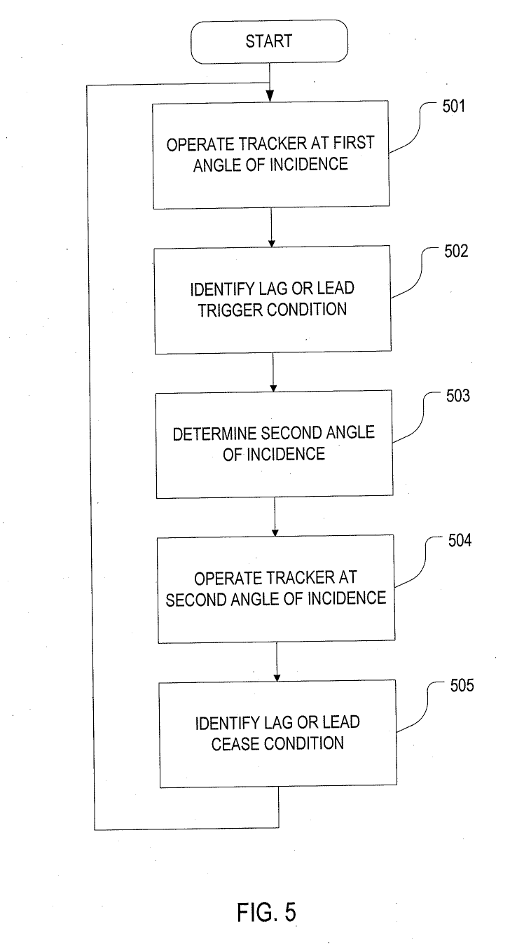

FIG. 5 illustrates an exemplary control algorithm executed by controllers 111 and 411 to operating electromechanical tracker 110 to cause solar modules 115 to track a position of the Sun at a desired angle of incidence. In a first step 501, the electromechanical tracker 110 is operated to cause solar modules 115 to track a position of the Sun at a first angle of incidence, generally the optimal angle of incidence. In response to identification of a lag or lead trigger condition (step 502), a second angle of incidence is determined (step 503) calculated by increasing or decreasing the first angle of incidence by a lagging or leading factor so as to change the electrical output of the solar module. Exemplary lag or lead trigger conditions include, as mentioned above, a temperature of the solar modules 115 being above a predetermined module temperature range or an ambient air temperature being above or below predetermined ambient air temperature range. Lag or lead trigger conditions can also be received from external sources, such as a clipping condition reported by an inverter electrically connected to the solar module or a decreased power output level command received from an inverter electrically connected to the solar module. The factors used in calculating the second angle of incidence can include, as mentioned above, a desired drop in a solar module 115 temperature, an expected decrease in the electrical current output of the solar modules 115, a desired decrease in the electrical current output of the solar modules 115, and/or a current air velocity and direction across the solar module.

Once the second angle of incidence is determined in step 503, in step 504 the electromechanical tracker 110 causes solar modules 115 to track a position of the Sun at the second angle of incidence, until such time as a lag or lead cease condition is identified. Such lag or lead cease conditions can include the solar modules 115 temperature returning to a predetermined module temperature range, the solar modules 115 temperature decreasing by a predetermined amount, ambient air temperature being above or below a predetermined ambient air temperature range, ambient air temperature decreasing by a predetermined amount, elapsing a predetermined amount of time or it being a predetermined time of day. Lag or lead cease conditions can also be received from external sources, such as a notification from an inverter electrically connected to the solar module that a clipping condition has ceased, or generated based on elapsed time, or selected to occur at a particular time of day.

The method illustrated in FIG. 5 can be applied by a common controller 411 to control a plurality of electromechanical trackers and a plurality of solar modules 115. The first and second angles of incidence can be the same for each of the solar modules 115, but, they can also be different, for instance, in cases where wind velocity or direction will have a greater effect on the operating temperatures of certain solar modules 115, but not others, or in cases where the lag or lead trigger condition comprises a decreased power output level command received from an inverter electrically connected to the solar modules, and the lagging or leading factor is calculated based on a desired decrease in the electrical current output of each solar module to meet the decreased power output level commanded by the inverter.

While several embodiments have been described in detail, it should be readily understood that the invention is not limited to the disclosed embodiments. Rather the embodiments can be modified to incorporate any number of variations, alterations, substitutions or equivalent arrangements not heretofore described. Although certain features have been described with some embodiments of the carrier, such features can be employed in other embodiments of the carrier as While several embodiments have been described in detail, it should be readily understood that the invention is not limited to the disclosed embodiments. Rather the embodiments can be modified to incorporate any number of variations, alterations, substitutions or equivalent arrangements not heretofore described. Although certain features have been described with some embodiments of the carrier, such features can be employed in other embodiments of the carrier as well. Accordingly, the invention is not limited by the foregoing description, but is only limited by the scope of the appended claims.

What is claimed as new and desired to be protected by Letters Patent of the United States is:

1. A method, comprising:
operating a tracker to cause a solar module to track a position of the sun at a first angle of incidence over a period of time;
in response to identification of a lag or lead trigger condition, determining a second angle of incidence as an increase or decrease from the first angle of incidence so as to change an electrical output of the solar module; and
operating the tracker to cause the solar module to track the position of the sun at the second angle of incidence.

2. The method of claim 1, wherein the lag or lead trigger condition comprises a solar module temperature being above a predetermined module temperature.

3. The method of claim 1, wherein the lag or lead trigger condition comprises an ambient air temperature being above or below a predetermined ambient air temperature range.

4. The method of claim 1, wherein the lag or lead trigger condition comprises an inverter clipping condition reported by an inverter electrically connected to the solar module.

5. The method of claim 1, wherein the lag or lead trigger condition comprises a desired power output level command received from one of an inverter electrically connected to the solar module or a power plant control system.

6. The method of claim 1, wherein the lag or lead trigger condition comprises a notification of incoming inclement weather.

7. The method of claim 1, wherein the first angle of incidence is an optimum angle of incidence for generating a maximum electrical output of the module.

8. The method of claim 1, further comprising:
operating the tracker to cause the solar module to return to tracking the position of the sun at the first angle of incidence in response to identification of a lag or lead cease condition.

9. The method of claim 8, wherein the lag or lead cease condition comprises a solar module temperature returning to below the predetermined module temperature.

10. The method of claim 8, wherein the lag or lead cease condition comprises a solar module temperature decreasing by a predetermined amount.

11. The method of claim 8, wherein the lag or lead cease condition comprises ambient air temperature being above or below predetermined ambient air temperature range.

12. The method of claim 8, wherein the lag or lead cease condition comprises ambient air temperature decreasing by a predetermined amount.

13. The method of claim 8, wherein the lag or lead cease condition comprises elapsing a predetermined amount of time.

14. The method of claim 8, wherein the lag or lead cease condition comprises a predetermined time of day.

15. The method of claim 8, wherein the lag or lead cease condition comprises a notification from an inverter electrically connected to the solar module that a clipping condition has ceased.

16. The method of claim 1, wherein the increase or decrease from the first angle of incidence is calculated based on an desired drop in a solar module temperature.

17. The method of claim 16, wherein the increase or decrease from the first angle of incidence is also calculated based on an expected decrease in the electrical current output of the solar module.

18. The method of claim 16, wherein the increase or decrease from the first angle of incidence is also calculated based on a desired decrease in the electrical current output of the solar module.

19. The method of claim 18, wherein the increase or decrease from the first angle of incidence is also calculated using a current air velocity and direction across the solar module.

20. The method of claim 1, wherein there are a plurality of trackers each for controlling the position of at least one solar module and the operating steps are performed for each of the electromechanical trackers to cause respective solar modules to track the position of the sun at the first and second angles of incidence.

21. The method of claim 20, wherein the first and second angles of incidence are the same for each of the solar modules.

22. The method of claim 20, wherein the first and second angles of incidence are the different for at least some of the solar modules.

23. The method of claim 20, wherein the lag or lead trigger condition comprises a decreased power output level command received from an inverter electrically connected to the solar modules, and the lagging or leading factor is calculated based on a desired decrease in the electrical current output of each solar module to meet the decreased power output level commanded by the inverter.

24. A system comprising:
a solar module mounted on a rotatable module support;
an electromechanical tracker operable to rotate the rotatable module support and solar module; and
a controller operable to:
operate a tracker to cause a solar module to track a position of the sun at a first angle of incidence over a period of time;
in response to identification of a lag or lead trigger condition, determine a second angle of incidence as an increase or decrease from the first angle of incidence so as to change an electrical output of the solar module; and
operate the tracker to cause the solar module to track the position of the sun at the second angle of incidence.

25. The system of claim 24, further comprising:
a plurality of solar modules mounted to rotatable module supports, each with electromechanical trackers operable to rotate the respective module supports and solar modules.

26. The system of claim 25, wherein each electromechanical has a separate controller.

27. The system of claim 25, wherein a common controller is connected to and controls at least a plurality of the electromechanical trackers.

28. The system of claim 24, further including a module temperature sensor connected to the solar module and wherein the lag or lead trigger condition comprises a solar module temperature being above a predetermined module temperature.

29. The system of claim 24, further including an ambient air temperature sensor connected to the solar module and wherein the lag or lead trigger condition comprises an ambient air temperature being above or below a predetermined ambient air temperature range.

30. The system of claim 24, wherein the lag or lead trigger condition comprises an inverter clipping condition reported by an inverter electrically connected to the controller.

31. The system of claim 24, wherein the lag or lead trigger condition comprises a desired power output level command received from one of an inverter electrically connected to the solar module or a power plant control system connected to the controller.

32. The system of claim 24, wherein the lag or lead trigger condition comprises a notification of incoming inclement weather.

33. The system of claim 24, wherein the first angle of incidence is an optimum angle of incidence.

34. The system of claim 24, wherein the controller is further operable to:
operating the tracker to cause the solar module to return to tracking the position of the sun at the first angle of incidence in response to identification of a lag or lead cease condition.

35. The system of claim 34, further including a module temperature sensor connected to the solar module and wherein the lag or lead cease condition comprises a solar module temperature returning to below the predetermined module temperature.

36. The system of claim 34, further including a module temperature sensor connected to the solar module and wherein the lag or lead cease condition comprises a solar module temperature decreasing by a predetermined amount.

37. The system of claim 34, further including an ambient air temperature sensor connected to the solar module and wherein the lag or lead cease condition comprises ambient air temperature being above or below predetermined ambient air temperature range.

38. The system of claim 34, further including an ambient air temperature sensor connected to the solar module and wherein the lag or lead cease condition comprises ambient air temperature decreasing by a predetermined amount.

39. The system of claim 34, wherein the lag or lead cease condition comprises elapsing a predetermined amount of time.

40. The system of claim 34, wherein the lag or lead cease condition comprises a predetermined time of day.

41. The system of claim 34, wherein the lag or lead cease condition comprises a notification from an inverter electrically connected to the controller that a clipping condition has ceased.

42. The system of claim 24, wherein the increase or decrease from the first angle of incidence is calculated based on an desired drop in a solar module temperature.

43. The system of claim 41, wherein the increase or decrease from the first angle of incidence is also calculated based on an expected decrease in the electrical output of the solar module.

44. The system of claim 41, wherein the increase or decrease from the first angle of incidence is also calculated based on a desired decrease in the electrical output of the solar module.

45. The system of claim 41, further including an air movement and direction sensor and wherein the increase or decrease from the first angle of incidence is also calculated using a current air velocity and direction across the solar module.
